(19) United States
(12) Patent Application Publication
(10) Pub. No.: US 2005/0057907 A1
(43) Pub. Date: Mar. 17, 2005

(54) Circuit board assembly

(75) Inventors: Gregory S. Meyer, Roseville, CA (US); Alisa C. Sandoval, Grass Valley, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P.

(21) Appl. No.: 10/661,433

(22) Filed: Sep. 12, 2003

(51) Int. Cl. H05K 7/10

(52) U.S. Cl. 361/785; 361/787; 361/803; 361/721

(57) ABSTRACT

A circuit board assembly includes an electronic component, a circuit board, a first connector portion coupled to one of the electronic component and the circuit board, a second connector portion coupled to the other of the electronic component and the circuit board, a first alignment member coupled to the first connector portion and a second alignment member coupled to the second connector portion. The second alignment member is configured to interact with the first alignment member to align the first connector portion with the second connector portion in at least one direction prior to engagement of the first connector portion and the second connector portion. The second alignment member extends relative to the second connector portion by a first extent prior to engagement of the first connector portion and the second connector portion. The second alignment member extends relative to the second connector portion by a second shorter extent upon engagement of the first connector portion and the second connector portion.

### BACKGROUND OF THE INVENTION

Computer systems and other electronic devices commonly employ a circuit board which functions as a communications highway between various electronic components secured to the circuit board. Some electronic components are permanently secured to the circuit board by such means as soldering. Other electronic components are releasably connected to the circuit board using one or more connectors which facilitate the transmission of signals between the electronic component and the circuit board. One example of such a connector is a pin and socket connector. Such connectors are frequently used to connect central processing units (CPUs) to a circuit board.

In many applications, the connectors used to connect the electronic component in the circuit board are relatively fragile or susceptible to deformation or bending. As a result, it is essential that the connector portion of the circuit board and the connector portion of the electronic component to be mounted to the circuit board be precisely aligned with one another during their connection. For example, it is important that the pins be precisely aligned with their corresponding sockets in those applications that employ pin and socket connectors.

In one known system for connecting a CPU to the mother board using a pin and socket connector, the sockets are provided with chamfers that guide the individual connector pins into the respective socket receptacles. The socket body additionally includes two protruding bosses that extend from the socket body located on the circuit board and which locate into corresponding slots in the CPU board. In addition, the CPU is surrounded with a picture-frame like shroud that locates on the outside of the socket body. Although these arrangements facilitate alignment of the pins with the sockets, such alignment does not occur before the pins of the CPU begin to engage the socket. As a result, the pins of such connectors are susceptible to stubbing and bending.

### BRIEF DESCRIPTION OF THE DRAWINGS

FIG. 1 is a side elevational view schematically illustrating one embodiment of a circuit board assembly of the present invention prior to engagement of a first connector portion coupled to an electronic component and a second connector portion coupled to a circuit board.

FIG. 2 is a side elevational view schematically illustrating the circuit board assembly of FIG. 1 with the first connector portion and the second connector portion in engagement with one another.

FIG. 3 is a side elevational view schematically illustrating a first alternative embodiment of the circuit board assembly of FIG. 1 illustrating the first connector portion and the second connector portion in engagement with one another.

FIG. 4 is a top plan view schematically illustrating a computing device incorporating a second alternative embodiment of the circuit board assembly of FIG. 1.

FIG. 5 is a perspective view illustrating the circuit board assembly of FIG. 4 in greater detail.

FIG. 6 is a side elevational view of the circuit board assembly of FIG. 5.

FIG. 7 is a sectional view of the circuit board assembly of FIG. 5 taken along line 7—7 illustrating an electronic component and a circuit board in a disconnected state.

FIG. 8 illustrates the circuit board assembly of FIG. 7 with a first alignment member coupled to the electronic component engaging a second alignment member coupled to the circuit board prior to engagement of a first connector portion coupled to the electronic component and a second connector portion coupled to the circuit board.

FIG. 9 illustrates the circuit board assembly of FIG. 7 with the first connector portion in engagement with the second connector portion and with the first alignment member in a retracted position.

FIG. 9a is a sectional view of the circuit board assembly of FIG. 9 taken along line 9a—9a.

FIG. 9b is a sectional view of the circuit board assembly of FIG. 9a taken along line 9b—9b.

FIG. 10 is a sectional view of a third alternative embodiment of the circuit board assembly of FIG. 1 incorporated into the computing device of FIG. 4 illustrating engagement between a first connector portion coupled to an electronic component and a second connector portion coupled to a circuit board.

### DETAILED DESCRIPTION OF EXAMPLE EMBODIMENTS

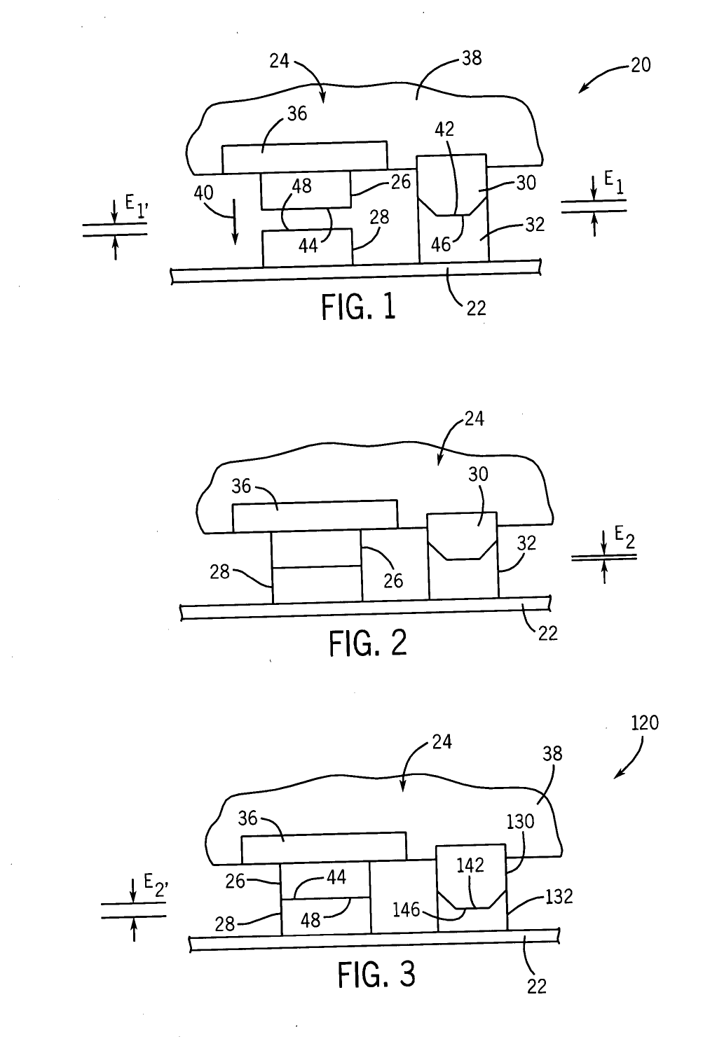

FIGS. 1 and 2 schematically illustrate circuit board support assembly 20, an example embodiment of the present invention. Circuit board support assembly 20 generally includes circuit board 22, electronic component 24, connector portion 26, connector portion 28, alignment member 30 and alignment member 32. Circuit board 22 comprises a conventionally known or future developed circuit board configured to transmit signals to and from various components connected to circuit board 22. Such components may be permanently secured to circuit board 22, such as resistors, capacitors and the like. Other components may be releasably connected to circuit board 22.

Electronic component 24 generally comprises an electronic component configured to be releasably connected to circuit board 22. In one embodiment, electronic component 24 may comprise a circuit board connected to circuit board 22. In another embodiment, electronic component 24 may comprise an active component such as an integrated circuit directly or indirectly connected to circuit board 22. For example, component 24 may comprise an integrated circuit directly connected to a connector which is connected to printed circuit board 22 or may comprise an integrated circuit connected to a circuit board which is connected to a connector connected to printed circuit board 22. The integrated circuit may also be connected to other structures in addition to circuit board 22. For example, electronic component 24 may include an integrated circuit such as a processor unit 36 connected to a heat sink 38.

Connector portions 26 and 28 engage and connect with one another to connect electronic component 24 to printed circuit board 22 so as to transmit signals to and from electronic component 24 and circuit board 22. In one embodiment, connector portion 26 may include a plurality of pins while connector portion 28 includes a plurality of sockets configured to receive the plurality of pins. In yet another embodiment, connector portion 26 may include a plurality of sockets while connector portion 28 includes a plurality of pins. In still other embodiments, connector portions 26 and 28 may comprise other conventionally known or future developed arrangements for connecting electronic component 24 to circuit board 22 and for transmitting signals in at least one direction between electronic component 24 and circuit board 22.

Alignment members 30 and 32 are coupled to electronic component 24 and circuit board 22, respectively. For purposes of this disclosure, the term “coupled” means the joining of two members directly or indirectly to one another. Such joining may be stationary in nature or movable in nature. Such joining may be achieved with the two members or the two members and any additional intermediate members being integrally formed as a single unitary body with one another or with the two members or the two members and any additional intermediate member being attached to one another. Such joining may be permanent in nature or alternatively may be removable or releasable in nature.

Alignment members 30 and 32 interact with one another to provide at least gross alignment of connector portions 26 and 28 prior to initial engagement and connection of connector portions 26 and 28. After initial engagement of alignment members 30 and 32, alignment members 30 and 32 either move and/or change shape to accommodate the continued movement of connector portion 26 towards connector portion 28 in the direction indicated by arrow 40 to enable connection of connector portions 26 and 28 without requiring perforations in circuit board 22. In particular, at least one of alignment members 30 and 32 has a terminal portion extending beyond a terminal portion of connector portion 26 or connector portion 28. In the particular embodiment illustrated alignment member 30 has a terminal portion 42 extending beyond terminal portion 44 of connector portion 26 while alignment member 32 has a terminal portion 46 extending beyond terminal portion 48 of connector portion 28. Terminal portions 42 and 46 are configured to mate with one another in a fashion so as to align connector portions 26 and 28 along at least one axis. Because portions 42 and 46 engage one another prior to engagement of connector portions 26 and 28, connector portions 26 and 28 are already in proper alignment with one another upon initial contact between connector portions 26 and 28, reducing the potential for damage to connector portions 26 and 28 caused by accidental misalignment of connector portions 26 and 28.

FIG. 2 illustrates continued movement of electronic component 24 and circuit board 22 towards one another until connector portions 26 and 28 connect with one another to connect component 24 to circuit board 22. As connector portions 26 and 28 are connected to one another, one or both of alignment members 30 and 32 move or change shape to accommodate the reduced spacing between component 24 and circuit board 22. In the particular embodiment illustrated, alignment member 30 moves or changes shape such that terminal portion 42 extends beyond terminal portion 44 by a different extent upon the connection of connector portions 26 and 28 as compared to when connector portion 30 and 32 are initially brought into engagement with one another. As shown by FIG. 1, terminal portion 42 of alignment member 30 extends beyond terminal portion 44 of connector portion 26 by a distance E1 when terminal portion 42 first contacts terminal portion 46 to align connector portions 26 and 28 in at least one direction.

As shown by FIG. 2, upon connection of connector portions 26 and 28, alignment member 30 moves or changes shapes such that terminal portion 42 extends relative to terminal portion 44 by a different extent. In particular, terminal portion 42 extends at a retracted position relative to terminal portion 44 of connector portion 26. Terminal portion 42 is retracted from terminal portion 44 by a distance E2. In alternative embodiments, alignment member 30 may be configured such that terminal portion 42 extends generally even with terminal portion 44 of connector portion 26.

FIG. 3 schematically illustrates circuit board assembly 120, a first alternative embodiment of circuit board assembly 20. Circuit board assembly 120 is identical to circuit board assembly 20 except that circuit board assembly 120 includes alignment members 130 and 132 in lieu of alignment members 30 and 32, respectively. For ease of illustration, those remaining components of circuit board assembly 120 which correspond to the components of circuit board assembly 20 are numbered similarly. Alignment members 130 and 132 include terminal portions 142 and 146, respectively. Like terminal portions 42 and 46, terminal portions 142 and 146 are configured to engage one another prior to connection of connector portions 26 and 28 to align connector portions 26 and 28. However, unlike alignment member 30, alignment member 130 is generally fixed relative to electronic component 24. Unlike alignment member 32, alignment member 132 moves or changes shape after terminal portions 142 and 146 are brought into engagement with one another and until connector portions 26 and 28 are moved into connection with one another. In particular, upon initial engagement of terminal portions 142 and 146, terminal portion 146 extends beyond terminal portion 48 of connector portion 28 by a distance E1′ depicted in FIG. 1. As circuit board 22 and component 24 are moved closer to one another so as to connect connector portions 26 and 28, alignment member 132 compresses or changes shape such that terminal portion 146 is retracted from terminal portion 48 by a distance E2′ shown in FIG. 3. Although assemblies 20 and 120 are illustrated as being configured such that one of the two alignment members compresses or changes shape, in alternative embodiments, both of the alignment members may be configured to move or change shape after initial alignment during the connection of connector portions 26 and 28.

Alignment member 132 may employ various configurations or mechanisms which facilitate their movement or change in shape to enable their terminal portions to move between an extended position and a retracted position relative to terminal portions of connectors 26 and 28 of at least one of connector portions 26 and 28. In one embodiment, alignment member 30 or 132 may comprise a movable pin. In one embodiment, the pin may be resiliently biased by a spring or other resiliently biased mechanism. In another embodiment, alignment member 30 or 132 may comprise a member which is rigid in a direction parallel to circuit board 22 but which is compressible in a direction perpendicular to circuit board 22. In one embodiment, alignment member 30 or 132 may include a bellows or other structure which functions similarly.

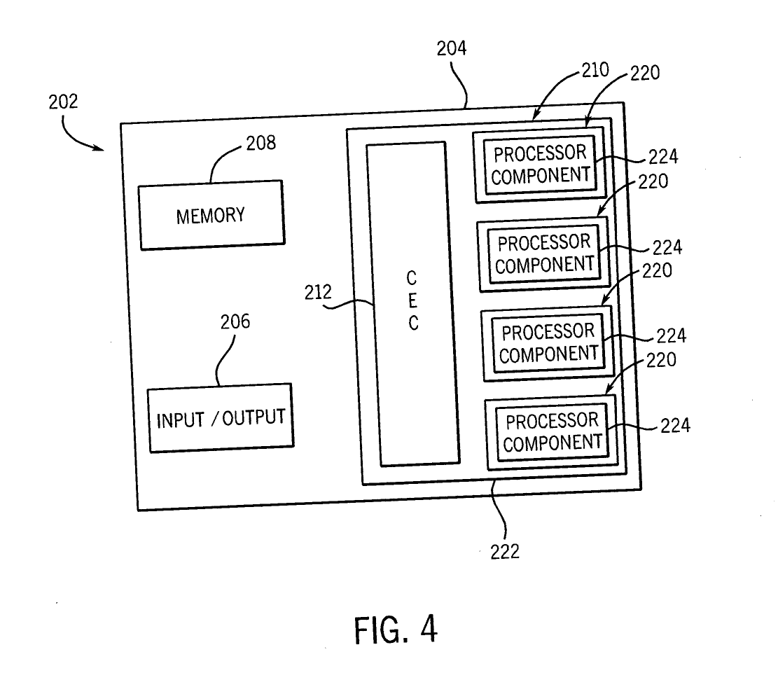

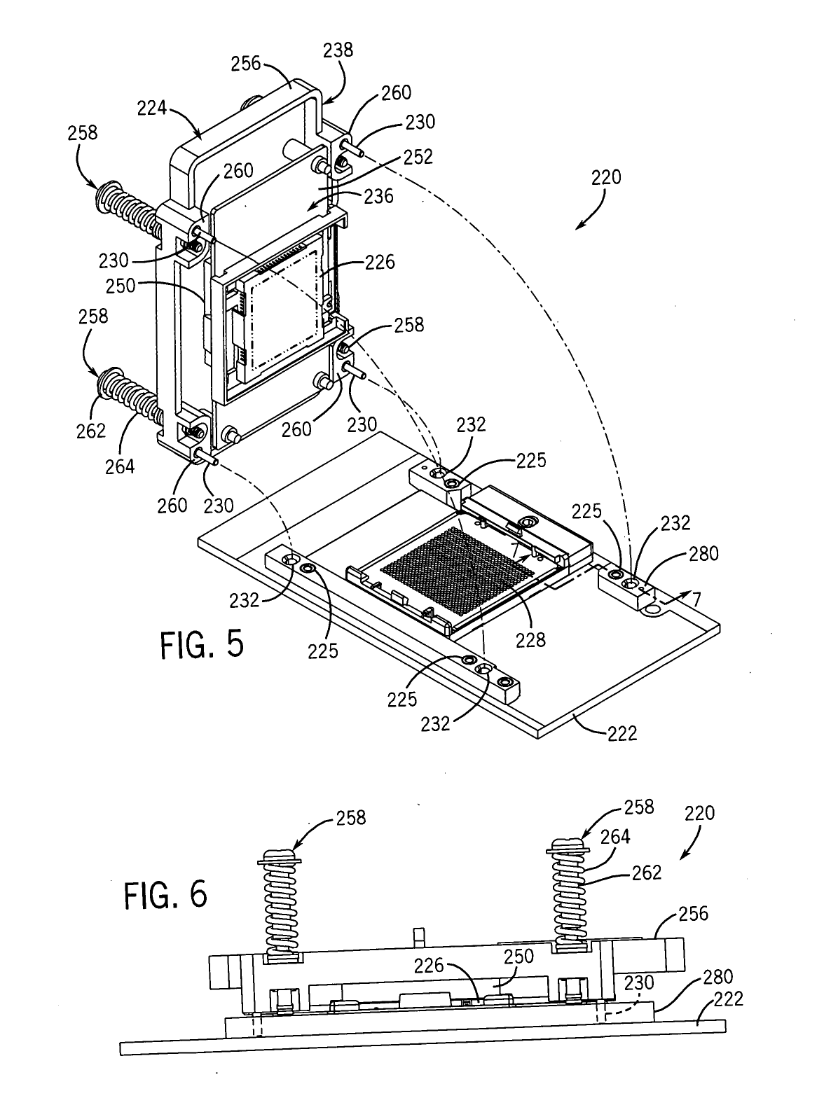

FIG. 4 schematically illustrates a computing device 202 incorporating circuit board assembly 220 (shown in FIGS. 5-9), a first embodiment of circuit board assembly 20 shown in FIG. 1. Computing device 202 (shown as a server) generally includes base board 204, input/output 206, memory 208 and processor system 210. Base board 204 connects input/output 206, memory 208 and processor system 210 and serves as an electronic highway between such units. Input/output 206 generally comprises an input/output board coupled to base board 204. The input/output board generally supports a plurality of input/output cards. Input/output 206 facilitates the use of additional peripherals such as tape drives, DVDs and the like with computing device 202.

Memory 208 is coupled to base board 204 and provides additional memory storage for computing device 202. In the particular embodiment shown, memory 208 comprises two memory extenders comprising boards carrying a plurality of memory cards.

Processor system 210 does much of the computing or calculations for computing device 202 and generally includes a processor board or circuit board 222, a plurality of processor components 224 and a control 212 (known as a computer electronic control or CEC). Circuit board 222 generally comprises a conventionally known or future developed circuit board (also known as a printed circuit assembly) capable of serving as an interface between the various elements connected to circuit board 222. Circuit board 222 is coupled to base board 22 and electronically connects each of processor components 224 to control 212.

Control 212 serves as a traffic cop between each of the processor components 224 and memory 208. Although not shown, computing device 20 may additionally include a power supply for supplying power to each of the components, one or more cooling fans and a housing for enclosing and supporting each of the components. Overall, input/output 206, memory 208 and processor system 210 cooperate with one another to provide information retrieval and processing.

FIGS. 5-9 illustrate circuit board assembly 220 which is incorporated into computing device 202. Circuit board assembly 220 includes circuit board 222, processor component 224, connector portion 226, connector portion 228, alignment members 230 and alignment members 232. Circuit board 222 is described above with respect to FIG. 4. However, as best shown by FIGS. 5 and 6, each of processor components 224 generally includes processor assembly 236 and heat sink assembly 238. Processor assembly 236 includes a conventionally known or future developed integrated circuit chip 250 configured to process information provided to it through circuit board 222 and mounted upon a circuit board 252 by which chip 250 is connected to connector portion 226.

Heat sink assembly 238 includes heat sink 256 and heat sink mounts 258. Heat sink 256 generally comprises a structure extending adjacent to chip 250 and bore 252 so as to dissipate heat generated by processor assembly 236. Although not illustrated, heat sink 256 may additionally include cooling fins to further facilitate the dissipation of heat. As shown by FIG. 1, heat sink 224 includes flats 260 configured to abut against connector portions 232 when connectors 226 and 228 are connected to one another.

Mounts 258 secure processor component 224 to circuit board 222. In the particular embodiment illustrated, mounts 258 each include a fastener 262 and a spring 264. Fastener 262 generally comprises an elongate bolt having a threaded end which extends through heat sink 256 and is configured to engage an opposite component mounting portion 225. Springs 264 comprise compression springs captured between a portion of fastener 262 and heat sink 256. Springs 264 resiliently bias component 224 towards circuit board 222. Springs 264 regulate the amount of force by which connector portion 226 is electrically connected to connector portion 228. In alternative embodiments, springs 264 may be omitted wherein fastener 262 directly bears against component 224 to couple component 224 to circuit board 222.

Component mounting portions 225 comprise structures secured to circuit board 222 and configured to interact with mount 258 to releasably couple component 224 to circuit board 222. In the particular embodiment illustrated, component mounting portions 225 comprise an internally threaded cylinder extending through alignment member 232 and into engagement with circuit board 222. In one embodiment, mounting portion 225 is pressed to circuit board 222. In another embodiment, mounting portion 222 threadably receives a fastener which captures circuit board 222 between its head and alignment member 232. In still other alternative embodiments, mounting portion 225 may comprise an internally threaded bore formed directly into alignment member 232. In still other embodiments, mounting portion 225 may be formed separate from connector member 232 and may have various other configurations depending upon the configuration of mount 258.

Connector portion 226 is configured to interact with connector portion 228 to connect chip 250 to circuit board 222 and to facilitate the transmission of signals therebetween. Connector portion 226 comprises a pin connector having a plurality of pins. Connector portion 228 is coupled to circuit board 222 and includes a plurality of sockets configured to receive the plurality of pins of connector portion 226. In the particular embodiment illustrated, connector portions 226 and 228 comprise a conventionally known zero-in-force (ZIF) connector sold by Intel. In alternative embodiments, connector portions 226 and 228 may comprise other conventionally known or future developed connector portions.

Alignment members 230 and 232 comprise two members configured to interact with one another so as to align in at least one direction the plurality of pins of connector portion 226 with their corresponding plurality of sockets provided by connector portion 228 prior to actual engagement of sockets of connector portion 228 by the pins of connector portion 226. At the same time, alignment member 230 is configured to move relative to a terminal portion of connector portion 226 (the ends of the pins) between an extended position in which each member 230 extends beyond the pins and a retracted position in which members 230 extend beyond the terminal ends of the pins of connector portion 226 by a lesser distance. In some instances, members 230 may actually be retracted so as to not extend past the terminal end portions of the pins of connector portion 226.

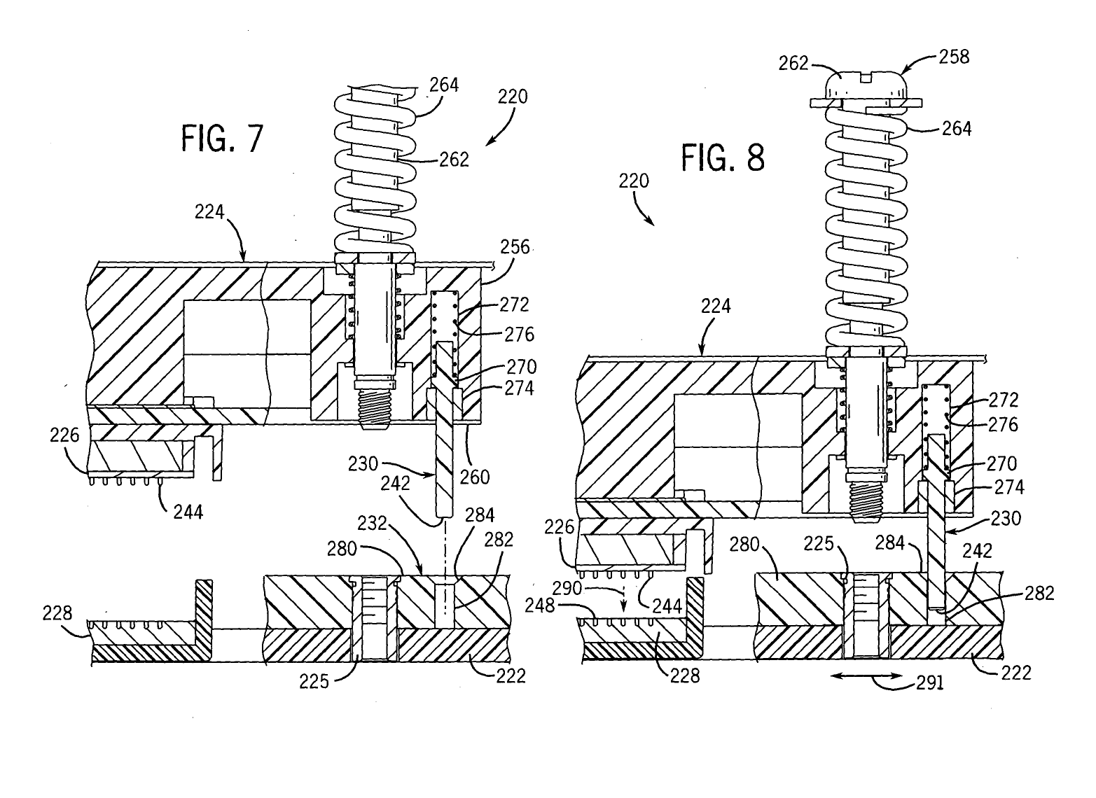

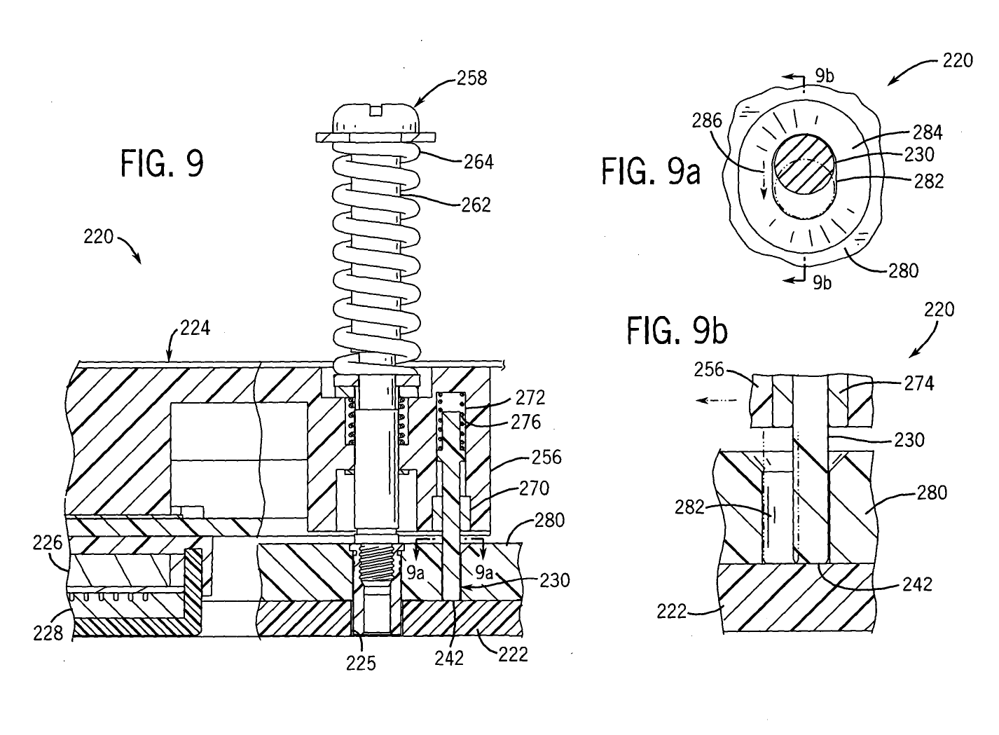

FIGS. 7-9 illustrate alignment members 230, 232 and the mounting of processor component 224 to circuit board 222 in greater detail. As best shown by FIGS. 7-9, each alignment member 232 generally comprises a detent while each alignment member 230 generally comprises a detent-engaging member. In the particular embodiment illustrated, each alignment member 230 comprises an elongate pin having a tip 242 and an annular collar 270. Collar 270 is captured by a sleeve or bushing 272 press fit within an elongate bore 272 formed within heat sink 256 adjacent to flat 260. Alignment member 230 generally moves within bore 272 and through bushing 274 between a fully extended position (shown in FIGS. 7 and 8) and a retracted position (shown in FIG. 9). In the extended position, collar 270 abuts bushing 274 and tip 242 extends beyond the terminal or end portions 244 of connector portion 226. As further shown by FIGS. 7 and 8, alignment member 230 is resiliently biased towards the extended position by a compression spring 276 captured within bore 272 between heat sink 256 and collar 270 of alignment member 230.

In the retracted position shown in FIG. 9, tip 242 extends relative to terminal portion 244 of connector portion 226 by a different extent. In the retracted position, collar 270 is urged against spring 276 to compress spring 276 such that a greater portion of alignment member 230 is received within bore 272. As a result, connector portions 226 and 228 may be brought into engagement with one another without acquiring alignment member 230 to project through circuit board 222 while alternatively minimizing the distance by which alignment member 230 must extend into circuit board 222.

As further shown by FIGS. 7-9, alignment member 232 includes a structure (shown as bracket 280) which forms a detent in the form of a bore 282 having a tapered or chamfered opening 284. In the particular embodiment illustrated, bracket 280 includes additional bores for reception of connection portions 225. In alternative embodiments, structure 280 may be dedicated solely to the provision of bore 282. Tapered opening 284 extends along the surface of structure 280 and further facilitates alignment of tip 242 of alignment member 230 into bore 282. Bore 282 is configured to closely engage the sides of alignment member 230 to facilitate alignment of connector portion 226 with connector portion 228 in at least one direction.

As shown by FIG. 9a, both bore 282 and opening 284 are generally ovular in shape such that alignment member 230 is permitted to move in the direction indicated by arrow 286 but is not permitted substantial movement in a direction perpendicular to arrow 286. As a result, the insertion of alignment member 230 into bore 282 aligns connector portion 226 with connector portion 228 in the direction perpendicular to arrow 286. In alternative embodiments, bore 282 and opening 284 may alternatively be configured as a circular opening so as to prevent movement of alignment member 230 in both the direction indicated by arrow 286 and the direction perpendicular to arrow 286 to also align connector portions 226 and 228 in both directions.

FIGS. 7-9 also illustrate the mounting of processor component 224 to circuit board 222. As shown by FIG. 7, processor component 224 is initially positioned over circuit board 222 with alignment member 230 generally aligned with alignment member 232 for engagement with alignment member 232. As shown by FIG. 8, processor component 224 is then moved towards circuit board 222 in the direction indicated by arrow 290. Prior to engagement of terminal portion 244 of connector portion 226 with terminal portion 248 of connector portion 228, tip 242 of alignment member 230 engages and is guided into bore 282 by tapered surface 284. This results in alignment of connector portion 226 with connector portion 228 in directions indicated by arrows 291. As shown by FIG. 9, movement of processor component 224 towards circuit board 222 continues until connector portion 226 and connector portion 228 are interconnected. Prior to complete interconnection of connector portions 226 and 228, tip 242 of alignment member 230 engages circuit board 222. The continued movement of processor component 224 towards circuit board 222 then results in movement of alignment member 230 and its collar 270 within bore 272 while compressing spring 276. As a result, tip 242 extends from bore 272 by a lesser extent as compared to the extent to which alignment member 230 extends from bore 272 prior to insertion of alignment member 230 into bore 282.

Once the pins of connector portion 226 have been inserted into the sockets of connector portion 228, a lever (not shown) is actuated to move connector portion 226 and the entire processor component 224 relative to connector portion 228 and circuit board 222. Such movement locks the pins of connector portion 226 in engagement with the sockets of connector portion 228. As best shown by FIGS. 9a and 9b, the generally ovular shape of bore 282 and tapered opening 284 accommodate such movement. Prior to such movement, fastener 262 is out of alignment (in the direction into the figure) with mounting portion 225. However, after such movement, fastener 262 is moved into alignment with mounting portion 225, whereby fastener 262 is then threaded into mounting portion 225 to secure processor component 224 to circuit board 222.

In alternative embodiments, bore 282 and surface 284 may have other configurations which permit the shifting of alignment member 230 within bore 282 during the shifting of connector portion 226 relative to connector portion 228. For example, bore 282 and surface 284 may alternatively comprise a rectangular slot. In alternative embodiments where connector portion 226 is not shifted relative to connector portion 228, bore 282 and tapered surface 284 may be circular in shape rather than ovular.

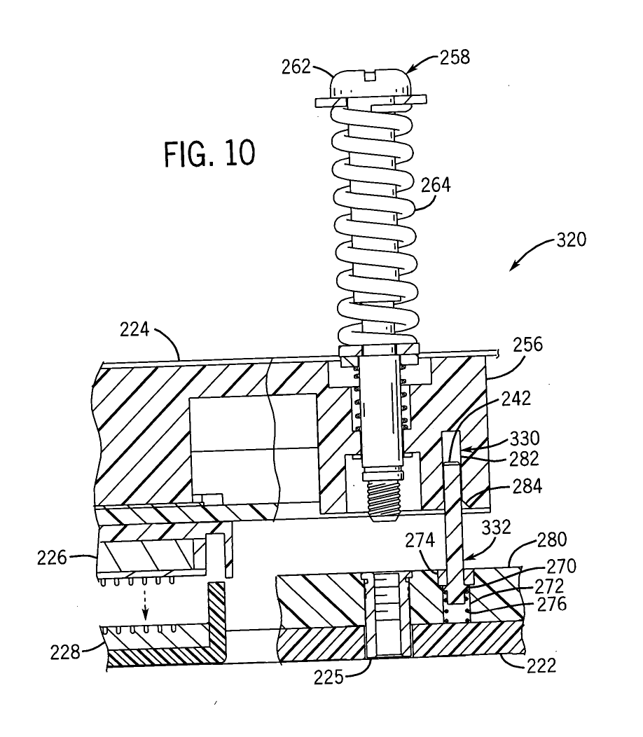

FIG. 10 illustrates circuit board assembly 320, a third alternative embodiment of assembly 20 shown in FIG. 1. Circuit board assembly 320 is illustrated as being incorporated into computing device 202 in lieu of assembly 220. Assembly 320 is substantially identical to assembly 220 except that assembly 320 includes alignment members 330 and 332 in lieu of alignment members 230 and 232, respectively. Alignment member 330 is substantially identical to alignment member 232 except that the structure providing bore 282 is provided by heatsink 256. Alignment member 332 is substantially identical to alignment member 230 except that bore 272 is formed within bracket 280 and bushing 274 is press fit within bracket 280.

During movement of processor component 224 towards circuit board 222, tip 242 initially engages tapered surface 284 and enters bore 282 to align connector portions 226 and 228 prior to engagement of connector portions 226 and 228. Although not shown, during connection of connector portions 226 and 228, tip 242 engages the end of bore 282 such that continued movement of component 224 towards circuit board 222 moves collar 270 towards circuit board 222 to compress spring 276. As a result, the extent to which tip 242 extends beyond bore 272 is reduced as compared to the extent to which tip 242 extends beyond bore 272 prior to insertion into bore 282. This enables the length of bore 282 to be reduced, enabling the overall height of heatsink 256 to also be reduced. Reducing the height of heatsink 256 facilitates a more compact processor component.

In the particular embodiment illustrated in FIG. 10, bore 282 and surface 284 have a generally ovular shape similar to that shown in FIGS. 5A and 5B to accommodate shifting of processor component 224 relative to circuit board 222. In alternative embodiments, bore 282 and bore 284 may have a circular shape or other configurations where such shifting is not performed.

Although the present invention has been described with reference to example embodiments, workers skilled in the art will recognize that changes may be made in form and detail without departing from the spirit and scope of the invention. For example, although different example embodiments may have been described as including one or more features providing one or more benefits, it is contemplated that the described features may be interchanged with one another or alternatively be combined with one another in the described example embodiments or in other alternative embodiments. Because the technology of the present invention is relatively complex, not all changes in the technology are foreseeable. The present invention described with reference to the example embodiments and set forth in the following claims is manifestly intended to be as broad as possible. For example, unless specifically otherwise noted, the claims reciting a single particular element also encompass a plurality of such particular elements.

1. A circuit board assembly comprising:
an electronic component;
a first circuit board;
a first connector portion coupled to one of the electronic component and the circuit board;
a second connector portion coupled to the other of the electronic component and the circuit board;
a first alignment member coupled to the first connector portion; and
a second alignment member coupled to the second connector portion, wherein the second alignment member is configured to interact with the first alignment member to align the first connector portion with the second connector portion in at least one direction prior to engagement of the first connector portion and the second connector portion, wherein the second alignment member extends relative to the second connector portion by a first extent prior to engagement of the first connector portion and the second connector portion and wherein the second alignment member extends relative to the second connector portion by a second shorter extent upon engagement of the first connector portion and the second connector portion.

2. The assembly of claim 1, wherein the first alignment member includes a structure forming a detent and wherein the second alignment member includes a detent-engaging structure.

3. The assembly of claim 2, wherein the detent has at least one tapered guide surface.

4. The assembly of claim 1, wherein the second alignment member is movably supported between a first position in which the second alignment member extends relative to the second connector portion by the first extent and a second position in which the member extends relative to the second connector portion by the second extent.

5. The assembly of claim 4, wherein the second connector portion is resiliently biased towards the first position.

6. The assembly of claim 5 including:
a structure coupled to the first connector portion forming a bore movably receiving the second alignment member; and
a spring received within the bore and biasing the second alignment member towards the first position.

7. The assembly of claim 6, wherein the structure comprises a heat sink assembly.

8. The assembly of claim 1, wherein the first alignment member is coupled to the circuit board and wherein the second alignment member is coupled to the electronic component.

9. The assembly of claim 8, wherein the second alignment member is directly coupled to a heat sink assembly coupled to the electronic component.

10. The assembly of claim 8, wherein the first alignment member includes a structure forming a bore configured to at least partially receive the second alignment member and wherein the bore terminates prior to extending into the circuit board.

11. The assembly of claim 1, wherein the second alignment member has a first configuration and wherein the second alignment member extends relative to the second connector portion by the first extent and has a second different configuration when the second alignment member extends relative to the second connector portion by the second extent.

12. The assembly of claim 1, wherein the first connector portion includes a plurality of pins and wherein the second connector portion includes a plurality of sockets configured to receive the plurality of pins.

13. The assembly of claim 1, wherein the electronic component comprises a processor unit.

14. The assembly of claim 1, wherein the electronic component comprises a second circuit board.

15. The assembly of claim 1 including:
a third alignment member coupled to the first connector portion; and
a fourth alignment member coupled to the second connector portion, wherein the fourth alignment member is configured to interact with the third alignment member to align the first connector portion with the second connector portion prior to engagement of the first connector portion and the second connector portion, wherein the fourth alignment member extends relative to the second connector portion by a first extent prior to engagement of the first connector portion and the second connector portion and wherein the fourth alignment member extends relative to the second connector portion by a second shorter extent upon engagement of the first connector portion and the second connector portion.

16. The assembly of claim 15 including:
a fifth alignment member coupled to the first connector portion; and
a sixth alignment member coupled to the second connector portion, wherein the sixth alignment member is configured to interact with the fifth alignment member to align the first connector portion with the second connector portion prior to engagement of the first connector portion and the second connector portion, wherein the sixth alignment member extends relative to the second connector portion by a first extent prior to engagement of the first connector portion and the second connector portion and wherein the sixth alignment member extends relative to the second connector portion by a second shorter extent upon engagement of the first connector portion and the second connector portion.

17. The assembly of claim 16 including:
a seventh alignment member coupled to the first connector portion; and
a eighth alignment member coupled to the second connector portion, wherein the eighth alignment member is configured to interact with the seventh alignment member to align the first connector portion with the second connector portion prior to engagement of the first connector portion and the second connector portion, wherein the eighth alignment member extends relative to the second connector portion by a first extent prior to engagement of the first connector portion and the second connector portion and wherein the eighth alignment member extends relative to the second connector portion by a second shorter extent upon engagement of the first connector portion and the second connector portion.

18. The assembly of claim 17, wherein the electronic component is a processor unit and wherein the processor unit is between each of the first alignment member, the third alignment member, the fifth alignment member and the seventh alignment member when the first connector portion and the second connector portion are connected.

19. A processor unit connecting system for use with a circuit board having a first connector portion and a first alignment member, the system comprising:
a processor unit;
a second connector portion coupled to the processor unit and configured to engage and connect to the first connector portion; and
a second alignment member coupled to the second connector portion, wherein the second alignment member is configured to interact with a first alignment member to align the first connector portion with the second connector portion prior to engagement of the first connector portion and the 11 second connector portion, wherein the second alignment member extends relative to the second connector portion by a first extent prior to engagement of the first connector portion and the second connector portion and wherein the second alignment member extends relative to the second connector portion by a second shorter extent upon engagement of the first connector portion and the second connector portion.

20. The system of claim 19, wherein the first alignment member includes a structure forming a detent and wherein the second alignment member includes a detent-engaging structure.

21. The assembly of claim 19, wherein the detent has at least one tapered guide surface.

22. The assembly of claim 19, wherein the second alignment member is movably supported between a first position in which the second alignment member extends relative to the second connector portion by the first extent and a second position in which the member extends relative to the second connector portion by the second extent.

23. The assembly of claim 22, wherein the second connector portion is resiliently biased towards the first position.

24. The assembly of claim 23 including:
a structure coupled to the first connector portion forming a bore movably receiving the second alignment member; and
a spring received within the bore and biasing the second alignment member towards the first position.

25. The assembly of claim 24, wherein the structure comprises a heat sink assembly.

26. The assembly of claim 19, wherein the second alignment member is directly coupled to a heat sink assembly coupled to the electronic component.

27. The assembly of claim 19, wherein the second alignment member has a first configuration and wherein the second alignment member extends relative to the second connector portion by the first extent and has a second different configuration when the second alignment member extends relative to the second connector portion by the second extent.

28. The assembly of claim 19, wherein the first connector portion includes a plurality of pins and wherein the second connector portion includes a plurality of sockets configured to receive the plurality of pins.

29. The assembly of claim 19 including:
a third alignment member coupled to the first connector portion; and
a fourth alignment member coupled to the second connector portion, wherein the fourth alignment member is configured to interact with the third alignment member to align the first connector portion with the second connector portion prior to engagement of the first connector portion and the second connector portion, wherein the fourth alignment member extends relative to the second connector portion by a first extent prior to engagement of the first connector portion and the second connector portion and wherein the fourth alignment member extends relative to the second connector portion by a second shorter extent upon engagement of the first connector portion and the second connector portion.

30. The assembly of claim 29 including:
a fifth alignment member coupled to the first connector portion; and
a sixth alignment member coupled to the second connector portion, wherein the sixth alignment member is configured to interact with the fifth alignment member to align the first connector portion with the second connector portion prior to engagement of the first connector portion and the second connector portion, wherein the sixth alignment member extends relative to the second connector portion by a first extent prior to engagement of the first connector portion and the second connector portion and wherein the sixth alignment member extends relative to the second connector portion by a second shorter extent upon engagement of the first connector portion and the second connector portion.

31. The assembly of claim 30 including:
a seventh alignment member coupled to the first connector portion; and
a eighth alignment member coupled to the second connector portion, wherein the eighth alignment member is configured to interact with the seventh alignment member to align the first connector portion with the second connector portion prior to engagement of the first connector portion and the second connector portion, wherein the eighth alignment member extends relative to the second connector portion by a first extent prior to engagement of the first connector portion and the second connector portion and wherein the 11 eighth alignment member extends relative to the second connector portion by a second shorter extent upon engagement of the first connector portion and the second connector portion.

32. The system of claim 31, wherein the processor unit is between each of the first alignment member, the third alignment member, the fifth alignment member and the seventh alignment member when the first connector portion and the second portion are connected.

33. The assembly of claim 1, wherein the first alignment member includes a structure forming a detent, wherein the second alignment member includes a detent-engaging structure and wherein the detent-engaging structure is movable within the detent in a first direction and is immovable within the detent in a second direction perpendicular to the first direction.

34. A circuit board connection system for use with an electronic component having a first connector portion and a first alignment member, the system comprising:
a circuit board;
a second connector portion coupled to the circuit board and configured to engage and connect to the first connector portion; and
a second alignment member coupled to the second connector portion, wherein the second alignment member is configured to interact with the first alignment member to align the first connector portion with the second connector portion in at least one direction prior to engagement of the first connector portion and the second connector portion, wherein the second alignment member extends relative to the second connector portion by a first extent prior to engagement of the first connector portion and the second connector portion and wherein the second alignment member extends relative to the second connector portion by a second shorter extent upon engagement of the first connector portion and the second connector portion.

35. A circuit board assembly comprising:
an electronic component;
a circuit board;
a first connector portion coupled to one of the electronic component and the circuit board;
a second connector portion coupled to the other of the electronic component and the circuit board; and
means for aligning the first connector portion and the second connector portion in at least one direction prior to engagement of the first connector portion and the second connector portion, wherein the means does not extend through the circuit board when the first connector portion is connected to the second connector portion.

36. The assembly of claim 35, wherein the electronic component comprises a processor unit.

37. The assembly of claim 35, wherein the first connector portion includes a plurality of pins and wherein the second connector portion includes a plurality of sockets configured to receive the plurality of pins.

38. A method for connecting the first connector portion of an electronic component to a second connector portion of a circuit board, the method comprising:
positioning a first alignment member coupled to one of the electronic component and the circuit board and extending beyond the second connector portion into engagement with a second alignment member coupled to the other of the electronic component and the circuit board prior to engagement of the first connector portion and the second connector portion to align the first connector portion with the second connector portion; and
moving at least a portion of the second alignment member relative to the second connector portion during connection of the first connector portion and the second connector portion to reduce an extent to which the second alignment member extends beyond the second connector portion.

39. A computing device comprising:
a baseboard;
a memory coupled to the baseboard;
input/output coupled to the baseboard; and
a processor system coupled to the baseboard, the processor system including:
a circuit board;
a central electronic control coupled to the circuit board;
a processor component;
a first connector portion coupled to one of the processor component and the circuit board;
a second connector portion coupled to the other of the processor component and the circuit board;
a first alignment member coupled to the first connector portion; and
a second alignment member coupled to the second connector portion, wherein the second alignment member is configured to interact with the first alignment member to align the first connector portion with the second connector portion prior to engagement of the first connector portion and the second connector portion, wherein the second alignment member extends relative to the second connector portion by a first extent prior to engagement of the first connector portion and the second connector portion and wherein the second alignment member extends relative to the second connector portion by a second shorter extent upon engagement of the first connector portion and the second connector portion.
